(19) United States
(12) Patent Application Publication
(10) Pub. No.: US 2014/0354310 A1
(43) Pub. Date: Dec. 4, 2014

(54) Capacitive Sensor Testing

(71) Applicant: Microsoft Corporation, Redmond, WA (US)

(72) Inventors: David C. Hargrove, Woodinville, WA (US); Dhaval M. Shah, Bellevue, WA (US); Robert E. Harris, JR., Woodinville, WA (US)

(73) Assignee: Microsoft Corporation, Redmond, WA (US)

(21) Appl. No.: 13/905,093

(22) Filed: May 29, 2013

(51) Int. Cl. G01R 31/28

(52) U.S. Cl. CPC G01R 31/2829
USPC 324/750.01

(57) ABSTRACT

Capacitive sensor testing techniques are described. In one or more implementations, a plurality of conductive pads of a test apparatus are caused to transition to a grounded state. The plurality of conductive pads is disposed proximal to one or more capacitive sensors of a device. An output is examined that describes a response of the one or more capacitive sensors of the device to the transition to the grounded state by the plurality of conductive pads to test operation of the one or more capacitive sensors of the device.

### BACKGROUND

Display and input techniques utilized by computing devices are ever evolving. For example, touchscreen and other devices have been developed which employ capacitive sensors that may be used to detect proximity of an object, such as one or more fingers of a user's hand, a stylus, and so on.

Conventional techniques that were utilized to test touchscreens, however, were often inaccurate and therefore were typically inadequate to test the touchscreen as suitable for intended use of the device. Further, these conventional techniques could be expensive, which may include use of a robot and specialized knowledge on the part of a technician to operate the robot to perform the test.

### SUMMARY

Capacitive sensor testing techniques are described. In one or more implementations, a plurality of conductive pads of a test apparatus are caused to transition to a grounded state. The plurality of conductive pads is disposed proximal to one or more capacitive sensors of a device. An output is examined that describes a response of the one or more capacitive sensors of the device to the transition to the grounded state by the plurality of conductive pads to test operation of the one or more capacitive sensors of the device.

In one or more implementations, a test apparatus includes a plurality of conductive pads and a plurality of switches. Each of the plurality of switches is communicatively coupled to a respective one of the plurality of conductive pads to transition different combinations of the plurality of conductive pads between grounded and ungrounded states to simulate an object and movement of the object for detection by a plurality of capacitive sensors of a touchscreen.

In one or more implementations, a device includes a touchscreen having a plurality of capacitive sensors and one or more modules implemented at least partially in hardware. The one or more modules are configured to test operation of the plurality of capacitive sensors through communication with a testing device, the testing device having a plurality of conductive pads that are configured for control by the one or more modules to transition between grounded and ungrounded states that are detected by the plurality of capacitive sensors.

This Summary is provided to introduce a selection of concepts in a simplified form that are further described below in the Detailed Description. This Summary is not intended to identify key features or essential features of the claimed subject matter, nor is it intended to be used as an aid in determining the scope of the claimed subject matter.

### BRIEF DESCRIPTION OF THE DRAWINGS

The detailed description is described with reference to the accompanying figures. In the figures, the left-most digit(s) of a reference number identifies the figure in which the reference number first appears. The use of the same reference numbers in different instances in the description and the figures may indicate similar or identical items.

FIG. 1 is an illustration of an environment in an example implementation that is operable to utilize capacitive sensor testing techniques described herein.

FIG. 2 is an illustration of a system in an example implementation showing a test apparatus and device of FIG. 1 in greater detail.

FIG. 3 depicts an example implementation of the test apparatus which includes a surface having a plurality of conductive pads.

FIG. 4 depicts an example system showing use of the test apparatus to test capacitive sensors of a device.

FIG. 5 depicts an example in which a duty cycle is configured to mimic proximity that does not involve contact of an object.

FIG. 6 is a flow diagram depicting a procedure in an example implementation in which a device having capacitive sensors is tested.

FIG. 7 illustrates various components of an example device that can be implemented as any type of computing device as described with reference to FIGS. 1-6 to implement embodiments of the techniques described herein.

### DETAILED DESCRIPTION

Overview

Conventional techniques that were utilized to test touchscreens were often expensive and difficult to reproduce, as these testing techniques could involve sophisticated robots and thus may also involve experienced technicians to control the robots. Other conventional techniques may involve manual manipulation of grounding rods by a technician. Consequently, these techniques may involve significant outlays in both time and other resources and thus may be expensive to perform.

Capacitive sensor testing techniques are described herein. In one or more implementations, techniques are described in which a touch input of a part of a user's body or other object (e.g., stylus) is simulated by using a one or more conductive pads that are transitioned between grounded and ungrounded states. The conductive pads may therefore support a variety of different tests that do not involve actual movement of the testing device. For example, the conductive pads may be transitioned at different points of time in succession to simulate movement of an object, e.g., a gesture.

Additionally, different combinations of the conductive pads may be transitioned to simulate different sizes of the object. Further, a duty cycle may be employed to perform a transition that mimics proximity that does not involve contact of the object, e.g., to mimic “hovering” of an object. Yet further, this testing may be performed by a device under test itself such that the device (e.g., a tablet computer, mobile communications device, and so on) controls operation of switches associated with the conductive pads. In this way, the device may cause the conductive pads to simulate an object and the device may determine whether capacitive sensors have detected the simulation without involving another computing device. Further discussion of these and other implementations may be found in relation to the following sections.

In the following discussion, an example environment is first described that may employ the testing techniques described herein. Example procedures are then described which may be performed in the example environment as well as other environments. Consequently, performance of the example procedures is not limited to the example environment and the example environment is not limited to performance of the example procedures.

Example Environment

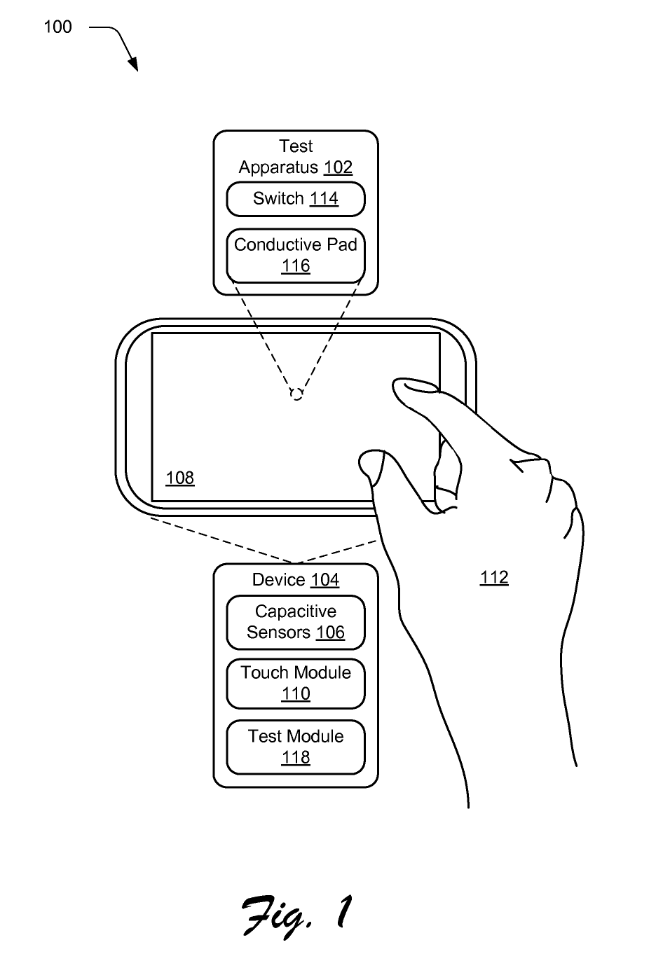

FIG. 1 depicts an environment 100 in an example implementation that includes a test apparatus 102 that is suitable to test a device 104 having one or more capacitive sensors. 106. The device 104 may be configured in a variety of ways. For example, the device 104 may be configured as a computing device, which may include a mobile communication device such as a mobile phone, a portable game-playing device, a tablet computer, as part of a traditional computing device (e.g., a display device that is part of a laptop or personal computer), and so on. The device 104 may also be configured as a capacitive touch pad or any other device that may employ capacitive sensors 106.

In the illustrated example, the capacitive sensors 106 are configured as part of a display device to form a touchscreen 108. For example, the capacitive sensors 106 of the touchscreen 108 may be configured to detect proximity (e.g., contact) with the touchscreen 106. In projected capacitance an X-Y grid may be formed across the touchscreen 108 using near optically transparent conductors (e.g., indium tin oxide) to detect proximity (e.g., contact) at different X-Y locations on the touchscreen 108. Other capacitance techniques are also contemplated, such as surface capacitance, mutual capacitance, self-capacitance, and so on. Thus, the capacitive sensors 106 may be configured in a variety of ways.

Regardless of the type of capacitive sensors 106 used, inputs detected by the capacitive sensors 106 may then be processed by a touch module 110 to detect characteristics of the inputs, which may be used for a variety of purposes. For example, the touch module 110 may recognize that the touch input indicates selection of a particular object, may recognize one or more inputs as a gesture usable to initiate an operation of the device 104 (e.g., expand a user interface), and so forth. This processing may rely upon the accuracy of the inputs and therefore operation of the device 104 and more particular capacitive sensors 106 of the device 104 may be tested to ensure that the device 104 is operating as intended.

In one or more implementations described herein, proximity of an object (e.g., such as one or more fingers of a user's hand 112) is emulated by the test apparatus 102. For example, the test apparatus 102 may include a switch 114 and a conductive pad 116. The switch 114 may be configured to cause the conductive pad 116 to alternate between grounded and ungrounded states. In this way, the switch 114 may effectively cause the conductive pad 116 to emulate a finger of a user's hand 112 or other object without moving the conductive pad 116, such as was previously involved in conventional robotic implementations. In other words, “up” and “down” touch events may mimic a press and removal of the user's finger without movement of the test apparatus 102.

A test module 118 may then be utilized to examine an output of the touch module 110 to test operation of the device 104 in recognizing touch inputs simulated by the test apparatus 102. Thus, in this example the “device under test” also causes performance and evaluation of the test. Other examples are also contemplated, such as to use one or more additional computing devices to control operation of the test apparatus 102, analysis of an output of the touch module 110, and so on. Further discussion of examples of testing may be found in the following discussion and shown in the corresponding figures.

Generally, any of the functions described herein can be implemented using software, firmware, hardware (e.g., fixed logic circuitry), or a combination of these implementations. The terms “module,” “functionality,” and “logic” as used herein generally represent software, firmware, hardware, or a combination thereof. In the case of a software implementation, the module, functionality, or logic represents program code that performs specified tasks when executed on a processor (e.g., CPU or CPUs). The program code can be stored in one or more computer readable memory devices. The features of the techniques described below are platform-independent, meaning that the techniques may be implemented on a variety of commercial computing platforms having a variety of processors.

For example, the test apparatus 102 and/or the device 104 may be implemented using a computing device. The computing device may also include an entity (e.g., software) that causes hardware of the computing device to perform operations, e.g., processors, functional blocks, a “system-on-a-chip,” and so on. For example, the computing device may include a computer-readable medium that may be configured to maintain instructions that cause the computing device, and more particularly hardware of the computing device to perform operations. Thus, the instructions function to configure the hardware to perform the operations and in this way result in transformation of the hardware to perform functions. The instructions may be provided by the computer-readable medium to the computing device through a variety of different configurations.

One such configuration of a computer-readable medium is signal bearing medium and thus is configured to transmit the instructions (e.g., as a carrier wave) to the hardware of the computing device, such as via a network. The computer-readable medium may also be configured as a computer-readable storage medium and thus is not a signal bearing medium. Examples of a computer-readable storage medium include a random-access memory (RAM), read-only memory (ROM), an optical disc, flash memory, hard disk memory, and other memory devices that may use magnetic, optical, and other techniques to store instructions and other data.

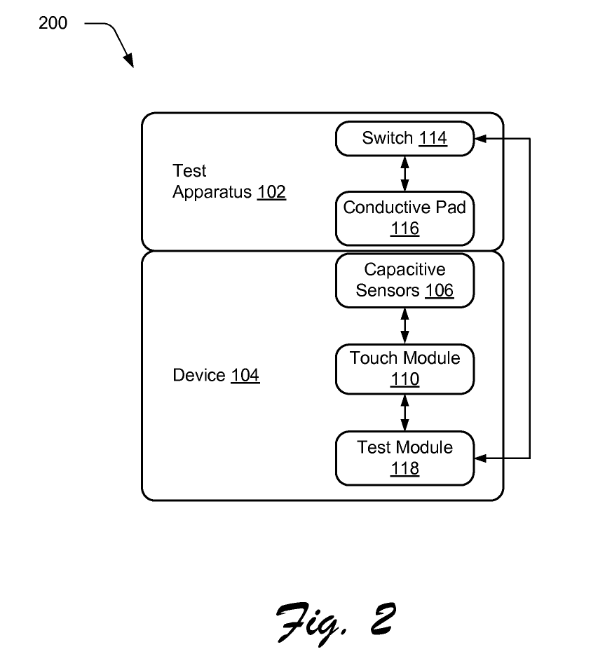

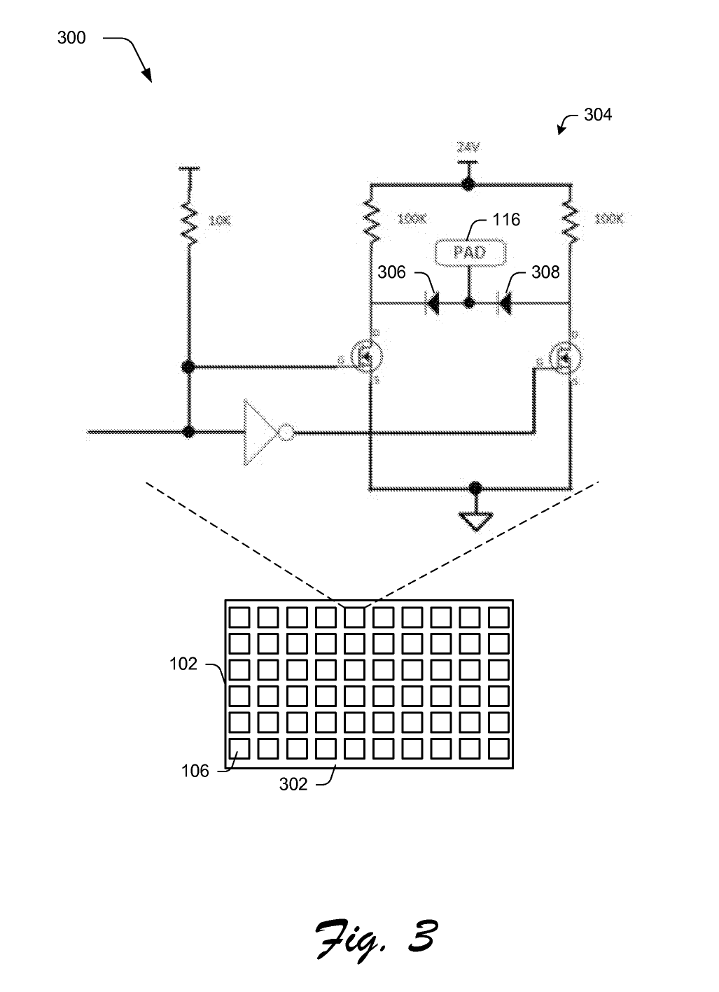

FIG. 2 is an illustration of a system 200 in an example implementation showing the test apparatus 102 and device of FIG. 1 in greater detail. In this example, the test apparatus 102 is illustrated as being disposed proximal to the device 104. This may include “setting” the test apparatus 102 on or near the touchscreen 108 of the device 108 such that the conductive pad 116 is disposed proximal to the capacitive sensors 106 such that grounding of the conductive pad 116 is detectable by the capacitive sensors 106. Further, the switch 114 is illustrated as being positioned on an opposing side of the conductive pad 116 that is away from the capacitive sensors 106. In this way, operation of the switch 114 may be shielded from detection by the capacitive sensors as further described in relation to FIG. 3.

In this example, the test module 118 is communicatively coupled to the test apparatus 102, which is configured to control operation of the switch 114 to simulate one or more touch inputs. As previously described, capacitive sensors 106 operate by detecting a change in capacitance to ground. For example, when a capacitive sensor 106 is touched with a finger of the user's hand 112, the human body provides the ground and the contact surface area of the finger acts as one of the plates of a capacitor. Thus, the capacitance to ground changes at the area where the finger has touched the surface in this example and thus may be used to detect “where” the contact has been achieved.

Accordingly, in this example the test module 118 may control capacitance between the conductive pad 116 with the capacitive sensors 106. For example, the test module 118 may interact with the switch 114 to control a transition between grounded and ungrounded states. The grounded state of the conductive pad 116 may simulate a “finger down” event of a touch input while the ungrounded state of the conductive pad 116 may be used to simulate a “finger up” event. Further, these transitions may be performed without physical movement and instead leverage electrical stimulation to simulate the input and

Thus, to test the device the test module 118 may cause the conductive pad 116 to transition between the grounded and ungrounded states. The ability of the capacitive sensors 106 and touch module 110 to detect and process these transitions may then be compared with what the test module 118 “knows” what happened (where and when the transitions are to occur) to test whether the device 104 is operating as intended. As previously described, although this example describes performance of the testing by the device under test itself, other examples are also contemplated. Further, the test apparatus 102 may assume a variety of different configurations to support a variety of different functionality, an example of which is described as follows and shown in a corresponding figure.

FIG. 3 depicts an example implementation 300 of the test apparatus 102 which includes a surface having a plurality of conductive pads 106. In this example, the test apparatus 102 includes a substrate 302 (e.g., a circuit board) having a plurality of conductive pads 106, which are illustrated as having a generally square shape but other examples are also contemplated. Each of the conductive pads 106 is connected to a respective switch to control a transition between grounded and ungrounded states as previously described. This functionality may be implemented in a variety of ways.

For example, a diagram of a circuit 304 is shown that may be associated with one of the plurality of conductive pads 116. Because the capacitive sensors 106 are configured to detect capacitance as previously described, the test apparatus 102 may be configured to provide little to no detectable capacitance to ground when the conductive pad 116 has been disconnected from ground.

The circuit 304, for instance, may leverage PIN diodes 306, 308 to apply and remove ground from the conductive pad 116. When the PIN diodes are forward biased the conductive pad 116 is connected to ground. When the PIN diodes 306, 308 are reverse biased, however, the conductive pad 116 is effectively isolated from ground. This is because the PIN diodes 306, 308 may be configured to have an extremely low reverse bias capacitance in comparison with other diodes.

As illustrated, the conductive pad 116 is placed in the middle of two PIN diodes 306, 308. Both diodes are used in this example because “V+” and ground may both provide paths to ground and thus the two PIN diodes 306, 308 may be used to isolate the conductive pad 116 from ground. The reverse-biased capacitance may be further reduced by adding additional diodes in series in the circuit 304. The test apparatus 102 may be leverage to support a variety of different tests, an example of which is described as follows and shown in a corresponding figure.

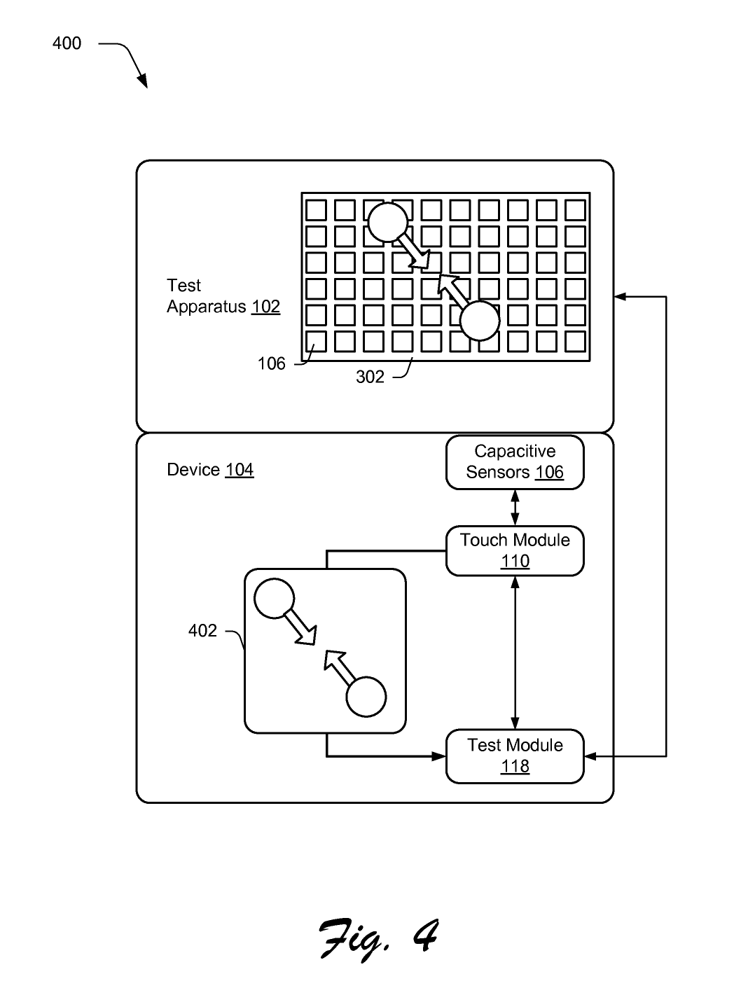

FIG. 4 depicts an example system 400 showing use of the test apparatus 102 to test capacitive sensors of a device 104. The test module 118 in this example is configured to control different combinations, sequences, and/or duty cycles for individual ones of an array of the plurality of conductive pads 106, which may be used to simulate a variety of different inputs.

For example, the test module 118 may cause a sequence of the conductive pads 106 to transition between ungrounded and grounded states to simulate a gesture such as a “pinch” gesture as illustrated. This transition may then be detected by the capacitive sensors 106 and processed by the touch module 110. A result 402 of this processing may then be compared with the instructed sequence to determine whether the device 104 is operating as intended to recognize the gesture.

The test apparatus 102 may also be utilized by the test module 118 to test detection of different sizes of objects as proximal to the capacitive sensors 106. For example, a group of conductive pads 106 may be transitioned together that simulates a size of a user's finger and a sub-group of these conductive pads 106 may be transitioned to simulate a stylus. Thus, these combinations may be utilized to simulate different sizes and shapes of inputs for detection by the capacitive sensors 106. A duty cycle of the transition may also be configured to support other testing functionality, which is further described as follows and shown in a corresponding figure.

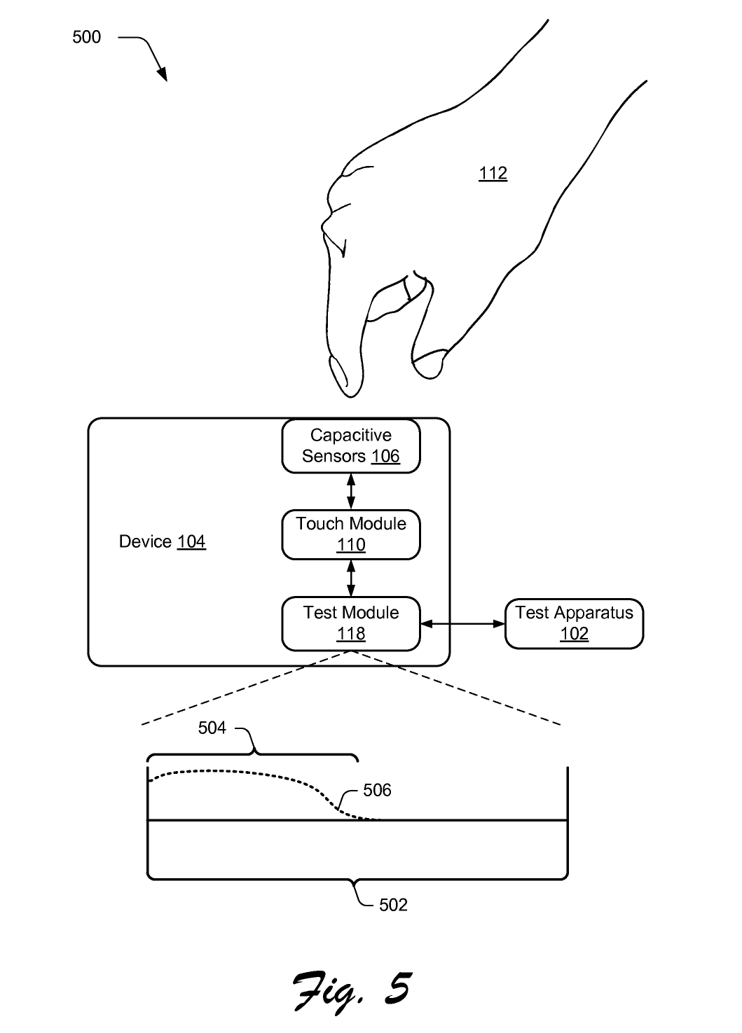

FIG. 5 depicts an example 500 in which a duty cycle is configured to mimic proximity but not touch of an object. In some instances, the device 104 may be configured to support functionality related to “hovering” of an object. For example, a finger of a user's hand 112 may be brought near a surface of a device 104 that includes the capacitive sensors 106 but not touch the surface. Thus, the finger of the user's hand 112 is considered as “hovering” over the device 104. Detection of the hover may be used in a variety of ways, such as to configure a user interface output by a touchscreen 108 and so on.

The test module 118 may be configured to specify a duty cycle between transitions of grounded and ungrounded states by the test apparatus 102 to simulate this hover. The capacitive sensors 106, for instance, may be configured to integrate inputs over a period of time 502 to define a “hover” versus an input that involves contact and so on. Accordingly, a duty cycle 504 may be used to switch from an ungrounded state to a grounded state and back again that is less than the period of time 502 such that overall integration during the period of time 502 causes the device 104 to recognize a “hover” and not a “touch,” i.e., to distinguish between the two. The test module 118, for instance, may cause the transitions such that an input 506 is detected by the capacitive sensors 106 and touch module 110.

This input 506, when integrated may be recognized as a hover due to the relatively short period of time in relation to the overall period of time used for detection by the touch module 110. Thus, the test module 118 may also utilize a duty cycle in the transitions as part of the testing of the device 104. A variety of other examples are also contemplated, such as to use different duty cycles to transition between conductive pads 106, different duty cycles between adjacent conductive pads 106 to mimic light and heavy touch inputs, and so on. Thus, the test apparatus 102 may be leveraged in a variety of ways to provide an efficient, accurate, and low cost way to test capacitive sensors 106 and subsequent processing of outputs by a device 104 that employs the sensors. Further discussion of these and other techniques may be found in relation to the following procedures.

Example Procedures

The following discussion describes capacitive sensor testing techniques that may be implemented utilizing the previously described systems and devices. Aspects of each of the procedures may be implemented in hardware, firmware, or software, or a combination thereof. The procedures are shown as a set of blocks that specify operations performed by one or more devices and are not necessarily limited to the orders shown for performing the operations by the respective blocks. In portions of the following discussion, reference will be made to FIGS. 1-5.

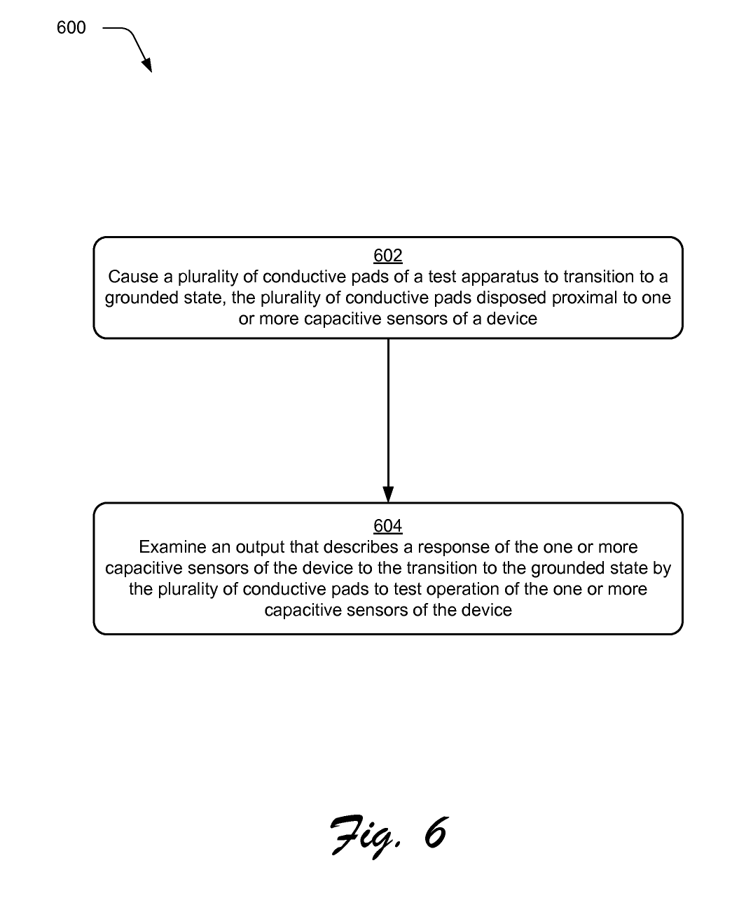

FIG. 6 is a flow diagram depicting a procedure 600 in an example implementation in which a device having capacitive sensors is tested. A plurality of conductive pads of a test apparatus are caused to transition to a grounded state, the plurality of conductive pads disposed proximal to one or more capacitive sensors of a device (block 602). The conductive pads 106, for instance, may be included as part of a surface 302 that is configured to be positioned proximal to a touchscreen 108 of a device 104 under test. Further, the device under test may be communicatively coupled to the test apparatus 102 to control transitions of the conductive pads 106 between ungrounded and grounded states to mimic touch inputs.

An output is examined that describes a response of the one or more capacitive sensors of the device to the transition to the grounded state by the plurality of conductive pads to test operation of the one or more capacitive sensors of the device (block 604). The test module 118, for instance, may compare the instructions given to the test apparatus 102 with results received from the touch module 110 to determine whether the device 104 is operating as intended. This may include testing the capacitive sensors 106 as well as subsequent processing of outputs of the capacitive sensors 106, e.g., by the touch module 110. A variety of other examples are also contemplated.

Example Device

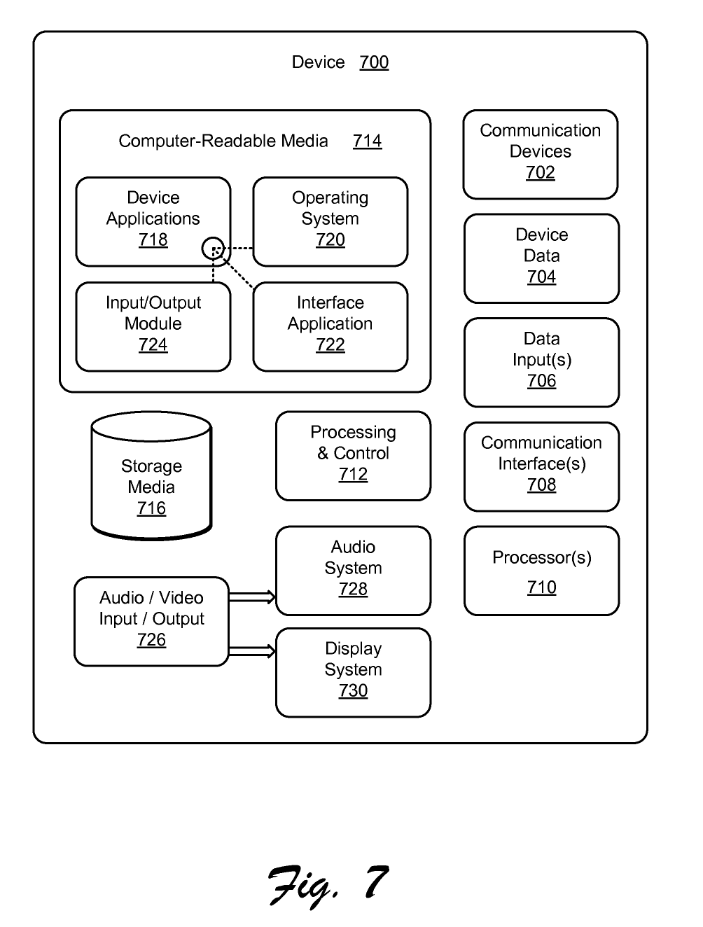

FIG. 7 illustrates various components of an example device 700 that can be implemented as any type of computing device as described with reference to FIGS. 1-6 to implement embodiments of the techniques described herein. Device 700 includes communication devices 702 that enable wired and/or wireless communication of device data 704 (e.g., received data, data that is being received, data scheduled for broadcast, data packets of the data, etc.). The device data 704 or other device content can include configuration settings of the device, media content stored on the device, and/or information associated with a user of the device. Media content stored on device 700 can include any type of audio, video, and/or image data. Device 700 includes one or more data inputs 706 via which any type of data, media content, and/or inputs can be received, such as user-selectable inputs, messages, music, television media content, recorded video content, and any other type of audio, video, and/or image data received from any content and/or data source.

Device 700 also includes communication interfaces 708 that can be implemented as any one or more of a serial and/or parallel interface, a wireless interface, any type of network interface, a modem, and as any other type of communication interface. The communication interfaces 708 provide a connection and/or communication links between device 700 and a communication network by which other electronic, computing, and communication devices communicate data with device 700.

Device 700 includes one or more processors 710 (e.g., any of microprocessors, controllers, and the like) which process various computer-executable instructions to control the operation of device 700 and to implement embodiments of the techniques described herein. Alternatively or in addition, device 700 can be implemented with any one or combination of hardware, firmware, or fixed logic circuitry that is implemented in connection with processing and control circuits which are generally identified at 712. Although not shown, device 700 can include a system bus or data transfer system that couples the various components within the device. A system bus can include any one or combination of different bus structures, such as a memory bus or memory controller, a peripheral bus, a universal serial bus, and/or a processor or local bus that utilizes any of a variety of bus architectures.

Device 700 also includes computer-readable media 714, such as one or more memory components, examples of which include random access memory (RAM), non-volatile memory (e.g., any one or more of a read-only memory (ROM), flash memory, EPROM, EEPROM, etc.), and a disk storage device. A disk storage device may be implemented as any type of magnetic or optical storage device, such as a hard disk drive, a recordable and/or rewriteable compact disc (CD), any type of a digital versatile disc (DVD), and the like. Device 700 can also include a mass storage media device 716.

Computer-readable media 714 provides data storage mechanisms to store the device data 704, as well as various device applications 718 and any other types of information and/or data related to operational aspects of device 700. For example, an operating system 720 can be maintained as a computer application with the computer-readable media 714 and executed on processors 710. The device applications 718 can include a device manager (e.g., a control application, software application, signal processing and control module, code that is native to a particular device, a hardware abstraction layer for a particular device, etc.). The device applications 718 also include any system components or modules to implement embodiments of the techniques described herein. In this example, the device applications 718 include an interface application 722 and an input/output module 724 (which may be the same or different as input/output module 74) that are shown as software modules and/or computer applications. The input/output module 724 is representative of software that is used to provide an interface with a device configured to capture inputs, such as a touchscreen, track pad, camera, microphone, and so on. Alternatively or in addition, the interface application 722 and the input/output module 724 can be implemented as hardware, software, firmware, or any combination thereof. Additionally, the input/output module 724 may be configured to support multiple input devices, such as separate devices to capture visual and audio inputs, respectively.

Device 700 also includes an audio and/or video input-output system 726 that provides audio data to an audio system 728 and/or provides video data to a display system 730. The audio system 728 and/or the display system 730 can include any devices that process, display, and/or otherwise render audio, video, and image data. Video signals and audio signals can be communicated from device 700 to an audio device and/or to a display device via an RF (radio frequency) link, S-video link, composite video link, component video link, DVI (digital video interface), analog audio connection, or other similar communication link. In an embodiment, the audio system 728 and/or the display system 730 are implemented as external components to device 700. Alternatively, the audio system 728 and/or the display system 730 are implemented as integrated components of example device 700.

### CONCLUSION

Although the invention has been described in language specific to structural features and/or methodological acts, it is to be understood that the invention defined in the appended claims is not necessarily limited to the specific features or acts described. Rather, the specific features and acts are disclosed as example forms of implementing the claimed invention.

What is claimed is:

1. A method comprising:
causing a plurality of conductive pads of a test apparatus to transition to a grounded state, the plurality of conductive pads disposed proximal to one or more capacitive sensors of a device; and
examining an output that describes a response of the one or more capacitive sensors of the device to the transition to the grounded state by the plurality of conductive pads to test operation of the one or more capacitive sensors of the device.

2. A method as described in claim 1, wherein the causing and the examining are performed by the device having the one or more capacitive sensors.

3. A method as described in claim 1, wherein the causing further includes transitioning the plurality of conductive pads to an ungrounded state.

4. A method as described in claim 3, wherein the transitioning to the grounded state and back to the ungrounded state has a duty cycle sufficient to mimic proximity of an object to a surface associated with the one or more capacitive sensors but not contact with the surface.

5. A method as described in claim 1, wherein the transitioning of the plurality of conductive pads to the grounded state is performed in succession at different points in time to mimic movement of an object proximal to the one or more capacitive sensors.

6. A method as described in claim 1, wherein the transitioning of the plurality of conductive pads to the ungrounded state is performed in succession at different points in time.

7. A method as described in claim 1, wherein the causing is performed to mimic input of a gesture.

8. A method as described in claim 1, wherein the one or more capacitive sensors are part of a touchscreen of the device.

9. A method as described in claim 1, wherein the one or more conductive pads are transitioned using PIN diodes.

10. A method as described in claim 1, wherein the causing is performed to simulate different sizes of objects for detection by the one or more capacitive sensors.

11. A test apparatus comprising:
a plurality of conductive pads; and
a plurality of switches, each being communicatively coupled to a respective one of the plurality of conductive pads to transition different combinations of the plurality of conductive pads between grounded and ungrounded states to simulate an object and movement of the object for detection by a plurality of capacitive sensors of a touchscreen.

12. A test apparatus as described in claim 11, wherein the plurality of switches are implemented at least in part using PIN diodes.

13. A test apparatus as described in claim 11, wherein the test apparatus is configured to be communicatively coupled to a device that includes the touchscreen such that the device is configured to operate the plurality of switches.

14. A test apparatus as described in claim 11, wherein the simulated movement of the object mimics a gesture.

15. A device comprising:
a touchscreen having a plurality of capacitive sensors; and
one or more modules implemented at least partially in hardware, the one or more modules configured to test operation of the plurality of capacitive sensors through communication with a testing device, the testing device having a plurality of conductive pads that are configured for control by the one or more modules to transition between grounded and ungrounded states that are detected by the plurality of capacitive sensors.

16. A device as described in claim 15, wherein the one or more modules are configured to cause the transitions to mimic movement of an object in relation the touchscreen.

17. A device as described in claim 15, wherein the one or more modules are configured to cause the transitions to employ a duty cycle sufficient to mimic proximity of an object to a surface of the touchscreen but not contact with the surface.

18. A device as described in claim 15, wherein the transitioning of the plurality of conductive pads is configured to be performed in succession at different points in time, respectively.

19. A device as described in claim 15, wherein the one or more modules are configured to cause transitioning of different combinations of the conductive pads to simulate different object sizes.

20. A device as described in claim 15, wherein the one or more conductive pads are transitioned using PIN diodes.
